(19) United States
(12) Patent Application Publication
(10) Pub. No.: US 2012/0298174 A1
(43) Pub. Date: Nov. 29, 2012

(54) ORGANIC THIN FILM SOLAR CELL

(75) Inventor: Hiroyuki Suzuki, Tokyo-to (JP)

(73) Assignee: DAI NIPPON PRINTING CO., LTD., Tokyo-to (JP)

(21) Appl. No.: 13/519,629

(22) PCT Filed: Nov. 25, 2010
(86) PCT No.: PCT/JP2010/071024

§ 371 Date: Jun. 28, 2012

(30) Foreign Application Priority Data
Jan. 7, 2010 (JP) 2010-002128

(51) Int. Cl. H01L 51/44; H01L 27/30

(52) U.S. Cl. 136/244; 136/256

(57) ABSTRACT

A principal object of the invention is to provide an organic thin film solar cell that makes it possible to protect an organic thin film from water and oxygen and to easily draw the power to the external circuit. To achieve the object, the invention provides an organic thin film solar cell comprising: a transparent substrate, a first electrode layer formed on the transparent substrate, a photoelectric conversion layer formed on the first electrode layer, and a second electrode layer that is formed on the photoelectric conversion layer and made of a metal base material.

### TECHNICAL FIELD

The invention relates to an organic thin film solar cell having a metal electrode.

### BACKGROUND ART

An organic thin film solar cell, which has an organic thin film placed between two different types of electrodes and having an electron donating function and an electron accepting function, is advantageous in that its manufacturing process is easier than that of an inorganic solar cell such as a silicon solar cell and it can be formed to have a large area at low cost.

An organic thin film solar cell has a basic structure including a layered structure of an anode electrode/an organic thin film/a cathode electrode. In general, one of the electrodes is a transparent electrode, the other electrode is a metal electrode, and the transparent electrode, the organic thin film, and the metal electrode are laminated in this order on a transparent substrate.

Methods that are generally used for forming the metal electrode include dry processes such as PVD processes including vacuum deposition, sputtering, and ion plating, and CVD processes; and wet processes in which coating is performed using a metal paste containing a colloidal metal such as silver (Ag), or other materials. In general, the thickness of the metal electrode is set from about several nm to several hundred nm.

In an organic thin film solar cell, the organic thin film is sometimes sealed so that it can be protected from water and oxygen. For example, there is proposed a structure sealed with a sealing substrate such as a glass substrate or a gas barrier film, in which a transparent electrode, an organic thin film, and a metal electrode are laminated in this order on a supporting substrate (transparent substrate) such as a glass substrate or a plastic film, and the supporting substrate and the sealing substrate are bonded together with a sealing agent so that the device is sealed.

Such a sealed structure needs additional power drawing wires for drawing power from the electrodes to the external circuit. For example, wires are formed between the supporting substrate and the sealing agent. In this case, the part where the wires are formed, which is difficult to seal, impairs the airtightness. Specifically, such wires are made of a metal material, while the sealing substrate is made of glass or an organic material, and therefore, the part where the wires and the sealing substrate are bonded has weak adhesion and reduced airtightness.

A method of embedding wires in a sealing substrate is proposed as a technique to solve this problem (see for example Patent Literature 1). However, such a structure is complicated and makes the manufacturing process laborious.

When a flexible solar cell is produced, a gas barrier film can be used as a sealing substrate. However, such a film is expensive.

### CITATION LIST

### Patent Literature

Patent Literature 1: Japanese Patent Application Laid-Open (JP-A) No. 2006-019285

### SUMMARY OF INVENTION

### Technical Problem

A principal object of the invention, which has been accomplished in view of the above circumstances, is to provide an organic thin film solar cell that makes it possible to protect the organic thin film from water and oxygen and to easily draw the power to the external circuit. Another object of the invention is to provide an inexpensive, flexible, organic thin film solar cell.

### Solution to Problem

To achieve the objects, the invention provides an organic thin film solar cell comprising: a transparent substrate, a first electrode layer formed on the transparent substrate, a photoelectric conversion layer formed on the first electrode layer, and a second electrode layer that is formed on the photoelectric conversion layer and made of a metal base material.

According to the invention, the second electrode layer is made of a metal base material such as a metal foil or a metal plate, so that the second electrode layer has barrier properties against water and oxygen and therefore can protect the photoelectric conversion layer from water and oxygen to suppress the degradation of the photoelectric conversion layer. In addition, the second electrode layer made of a metal base material, which has barrier properties against water and oxygen, does not need to be sealed from above using a sealing substrate, and the power can be easily drawn from the first and second electrode layers to the external circuit.

In the invention, an adhesive layer having insulating properties is preferably formed along an outer periphery of the photoelectric conversion layer and between the first electrode layer and the second electrode layer. The first and second electrode layers can be directly bonded together with the adhesive layer interposed therebetween, so that the photoelectric conversion layer can be sealed with high airtightness. This can prevent water and oxygen from entering the photoelectric conversion layer and effectively suppress the degradation of the photoelectric conversion layer. Since the adhesive layer has insulating properties, no short circuit occurs between the first and second electrode layers.

Also in the invention, the metal base material is preferably a metal foil. When the metal base material is a metal foil, an organic thin film solar cell having flexibility can be obtained at low cost.

The invention also provides an organic thin film solar cell module comprising: a plurality of the organic thin film solar cells connected in series or parallel.

According to the invention, the power can be easily drawn from the first and second electrode layers to the external circuit as described above, and a plurality of the organic thin film solar cells can be easily connected using the first and second electrodes layers.

### Advantageous Effects of Invention

The invention produces the advantageous effect that the second electrode layer, made of a metal base material such as a metal foil or a metal plate, can protect the photoelectric conversion layer from water and oxygen to suppress the degradation of the photoelectric conversion layer, the second electrode layer does not need to be sealed from above using a sealing substrate, and the power can be easily drawn from the first and second electrode layers to the external circuit.

### BRIEF DESCRIPTION OF DRAWINGS

FIG. 1 is a schematic cross-sectional view showing an example of the organic thin film solar cell of the invention.

FIGS. 2A and 2B are schematic plan and cross-sectional views, respectively, showing another example of the organic thin film solar cell of the invention.

FIGS. 3A, 3B, and 3C are schematic plan and cross-sectional views, respectively, showing a further example of the organic thin film solar cell of the invention.

FIG. 4 is a schematic cross-sectional view showing a further example of the organic thin film solar cell of the invention.

FIG. 5 is a schematic cross-sectional view showing a further example of the organic thin film solar cell of the invention.

FIG. 6 is a schematic cross-sectional view showing an example of the organic thin film solar cell module of the invention.

### DESCRIPTION OF EMBODIMENTS

Hereinafter, a detailed description is given of the organic thin film solar cell and the organic thin film solar cell module of the invention.

A. Organic Thin Film Solar Cell

The organic thin film solar cell of the invention comprises: a transparent substrate, a first electrode layer formed on the transparent substrate, a photoelectric conversion layer formed on the first electrode layer, and a second electrode layer formed on the photoelectric conversion layer and made of a metal base material.

The organic thin film solar cell of the invention is described with reference to the drawings.

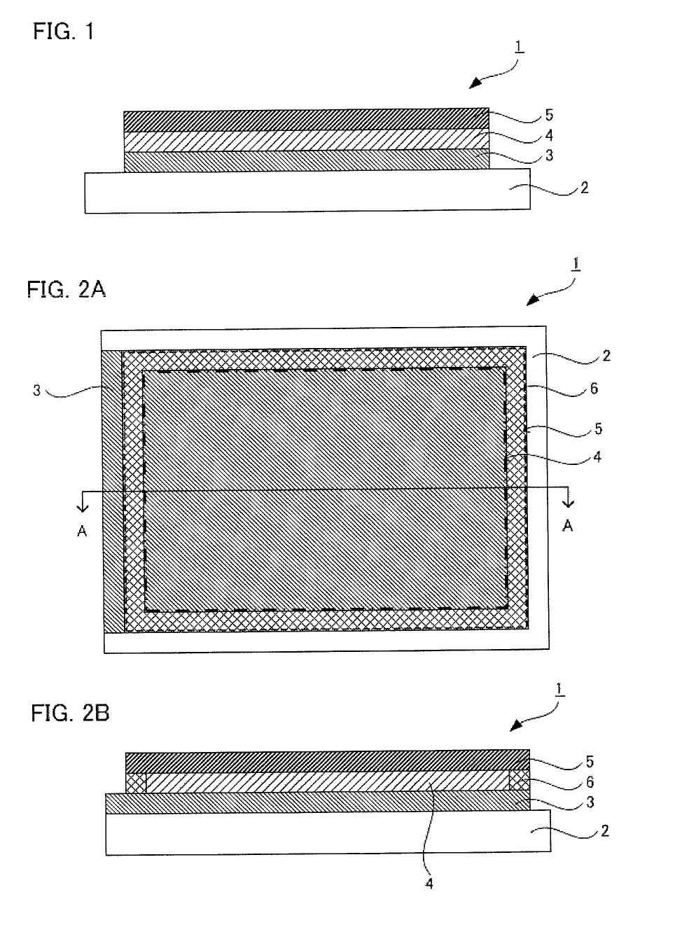

FIG. 1 is a schematic cross-sectional view showing an example of the organic thin film solar cell of the invention. In the example shown in FIG. 1, an organic thin film solar cell 1 comprises: a transparent substrate 2, a first electrode layer 3 formed on the transparent substrate 2, a photoelectric conversion layer 4 formed on the first electrode layer 3, and a second electrode layer 5 that is formed on the photoelectric conversion layer 4 and made of a metal base material. The photoelectric conversion layer 4 and the second electrode layer 5 have the same area.

According to the invention, the second electrode layer is made of a metal base material such as a metal foil or a metal plate, so that water and oxygen can be prevented from penetrating from the second electrode layer side. Therefore, the second electrode layer can protect the photoelectric conversion layer from water and oxygen to suppress the degradation of the photoelectric conversion layer.

According to the invention, the second electrode layer is made of a metal base material and has barrier properties against water and oxygen, so that the second electrode layer does not need to be sealed from above using a sealing substrate. Therefore, the power can be easily drawn from the first and second electrode layers to the external circuit. In addition, this can simplify the structure of the organic thin film solar cell, so that the manufacturing process can be simplified.

FIGS. 2A and 2B are schematic plan and cross-sectional views, respectively, showing another example of the organic thin film solar cell of the invention, and FIG. 2B is a cross-sectional view along the A-A line in FIG. 2A. In FIG. 2A, a photoelectric conversion layer 4 is indicated by an alternate long and short dash line, and a second electrode layer 5 is indicated by a broken line. FIGS. 2A and 2B show an organic thin film solar cell 1 comprising: a transparent substrate 2, a first electrode layer 3 formed on the transparent substrate 2, a photoelectric conversion layer 4 formed on the first electrode layer 3, a second electrode layer 5 that is formed on the photoelectric conversion layer 4 and made of a metal base material, and an adhesive layer 6 that has insulating properties and is formed between the first and second electrode layers 3 and 5 so as to surround the outer periphery of the photoelectric conversion layer 4. Since the adhesive layer 6 has insulating properties, no short circuit occurs between the first and second electrode layers 3 and 5.

In the organic thin film solar cell, the first and second electrode layers can be directly bonded together with the adhesive layer interposed therebetween. As described above, the second electrode layer made of a metal base material has barrier properties against water and oxygen, so that the second electrode layer does not need to be sealed from above using a sealing substrate, and the power can be easily drawn from the first and second electrode layers to the external circuit. Therefore, there is no need to provide any power drawing wire between the transparent substrate and the adhesive layer in contrast to a conventional way. Thus, the airtightness is not lost by any part where the wire is provided. In addition, since the first and second electrode layers are each made of an electrically-conductive material such as a metal or a metal oxide, the adhesive layer has good adhesion to both of the first and second electrode layers. Thus, the formation of the adhesive layer enables highly tight sealing of the photoelectric conversion layer. As a result, water and oxygen can be prevented from entering the photoelectric conversion layer, and the degradation of the photoelectric conversion layer can be effectively suppressed.

In addition, when the metal base material is a metal foil, an organic thin film solar cell having flexibility can be provided, because the metal foil has barrier properties against water and oxygen even when it is thin. Therefore, a flexible organic thin film solar cell can be obtained at low cost with no need for an expensive gas barrier film.

Hereinafter, a description is given of each component of the organic thin film solar cell of the invention.

1. Second Electrode Layer

In the invention, the second electrode layer is formed on the photoelectric conversion layer and made of a metal base material. In general, the second electrode layer is used as an electrode for extracting electrons generated in the photoelectric conversion layer (an electron extraction electrode).

The second electrode layer has barrier properties against water and oxygen. The second electrode layer preferably has a water vapor transmission rate of 1×10⁻² g/(m²·day) or less, more preferably 1×10⁻³ g/(m²·day) or less, and in particular, preferably 1×10⁻⁴ g/ (m²−day) or less. It should be noted that since the water vapor transmission rate is preferably as low as possible, no lower limit is specified. The second electrode layer also preferably has an oxygen transmission rate of 1×10⁻⁴ ml/(m²·day) or less. It should be noted that since the oxygen transmission rate is preferably as low as possible, no lower limit is specified.

Here, the water vapor transmission rate is the value measured using a water vapor transmission rate meter (PERMATRA™ manufactured by MOCON Inc.). The oxygen gas transmission rate is the value measured using an oxygen transmission rate meter (OX-TRAN™ manufactured by MOCON Inc.).

The metal base material may be in any shape such as a metal foil or a metal plate. In particular, a metal foil is preferably used. When the metal base material is a metal foil, an organic thin film solar cell having flexibility can be obtained at low cost.

As used herein, the term “metal foil” refers to a material having flexibility. The term “metal plate” refers to a material having no flexibility.

Herein, when the metal base material has flexibility, it means that the metal base material can be bent by applying a force of 5 KN in the metallic material bend test according to JIS Z 2248.

The metal base material is made of any metal material that can function as an electrode, form a metal foil or a metal plate, and have the barrier properties described above. In particular, when the second electrode layer is an electron extraction electrode, the metal material preferably has a low work function. Examples of the metal material include aluminum, copper, titanium, chromium, tungsten, molybdenum, platinum, tantalum, niobium, zirconium, zinc, silver, gold, various stainless steels, and alloys thereof. In particular, aluminum and silver are preferred.

The metal base material may have any thickness that enables the metal base material to function as an electrode and have the barrier properties described above. Specifically, the thickness of the metal base material should be 10 μm or more and may be from about 10 μm to about 3 mm. The thicker the metal base material is, the better the conductivity or the barrier properties is. On the other hand, the thinner the metal base material is, the higher the flexibility is. In view of flexibility, the metal base material preferably has a thickness in the range of 10 μm to 300 μm, and more preferably in the range of 30 μm to 300 μm.

The method of preparing the metal base material may be any method by which a single piece of metal base material is obtained. Common methods may be used, which may be appropriately selected depending on factors such as the type of the metal material or the thickness of the metal base material.

The second electrode layer may be formed at any position as long as the second electrode layer is formed on the photoelectric conversion layer so as to protect the photoelectric conversion layer from water and oxygen and so placed that no short circuit occurs between the first and second electrode layers. For example, as shown in FIG. 1, the second electrode layer 5 may be formed to have the same area as the photoelectric conversion layer 4. In this case, the second electrode layer and the photoelectric conversion layer have the same area, so that the second electrode layer can protect the photoelectric conversion layer and that no short circuit occurs between the first and second electrode layers. Alternatively, as shown in FIGS. 2A and 2B, the second electrode layer 5 may be formed to have an area larger than that of the photoelectric conversion layer 4, and the adhesive layer 6 having insulating properties may be formed on the part between the second electrode layer 5 and the first electrode layer 3 and where the photoelectric conversion layer 4 is not formed. In this case, the second electrode layer has an area larger than that of the photoelectric conversion layer, so that the second electrode layer can protect the photoelectric conversion layer and that the formation of the adhesive layer having insulating properties prevents a short circuit between the first and second electrode layers.

The method of forming the second electrode layer on the photoelectric conversion layer may be any method by which the second electrode layer made of a metal base material can be placed with good adhesion onto the photoelectric conversion layer, and for example, a method of thermocompression-bonding the metal base material onto the photoelectric conversion layer may be used. Since the photoelectric conversion layer may contain an organic material such as a conductive polymer material, the thermal lamination of the metal base material onto the photoelectric conversion layer makes it possible to laminate the metal base material with good adhesion.

2. Adhesive Layer

In the invention, an adhesive layer having insulating properties is preferably formed along the outer periphery of the photoelectric conversion layer and between the first electrode layer and the second electrode layer. To prevent a short circuit between the first and second electrode layers, it is preferred that the adhesive layer should be always formed between the first and second electrode layers and on the part where the photoelectric conversion layer is not formed.

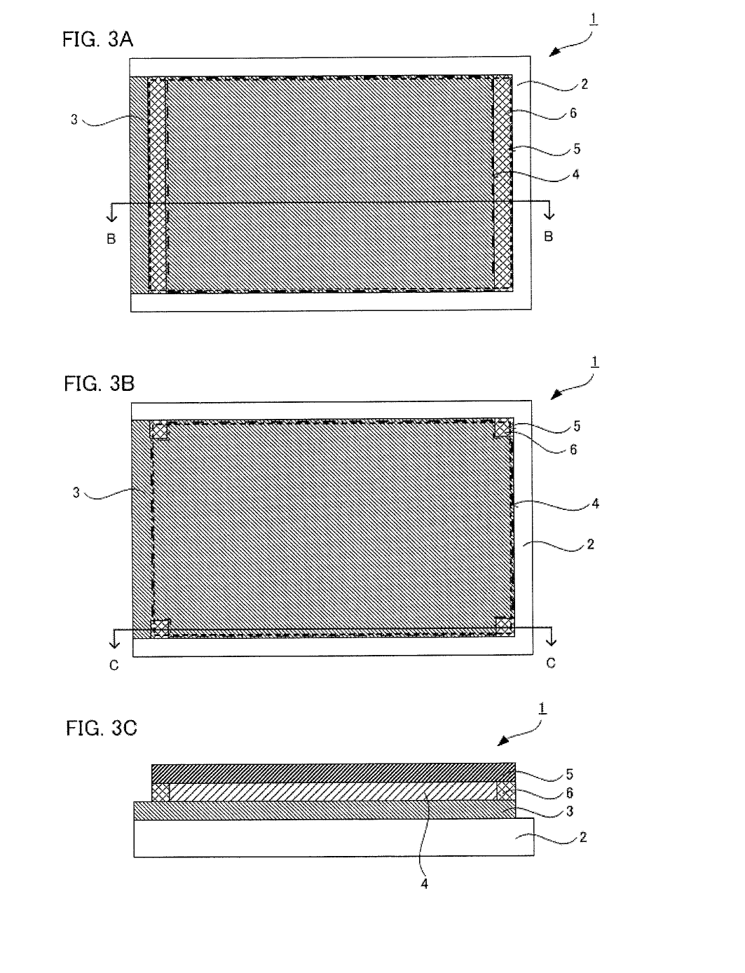

The adhesive layer may be formed at any position as long as the adhesive layer is formed along the outer periphery of the photoelectric conversion layer and between the first and second electrode layers and so placed that no short circuit occurs between the first and second electrode layers. For example, as shown in FIGS. 2A and 2B, the adhesive layer 6 may be formed so as to surround the outer periphery of the photoelectric conversion layer 4 and between the first and second electrode layers 3 and 5, or as shown in FIGS. 3A to 3C, the adhesive layer 6 may be formed along part of the outer periphery of the photoelectric conversion layer 4 and between the first and second electrode layers 3 and 5. FIG. 3C is a cross-sectional view along the B-B line in FIG. 3A and along the C-C line in FIG. 3B. In FIGS. 3A and 3B, the photoelectric conversion layer 4 is indicated by an alternate long and short dash line, and the second electrode layer 5 is indicated by a broken line. Although not shown, when the photoelectric conversion layer is rectangular, the adhesive layer may be formed so as to surround the four sides of the photoelectric conversion layer, formed along three sides of the photoelectric conversion layer, formed along two sides of the photoelectric conversion layer, or formed along one side of the photoelectric conversion layer. In any case, as described above, the adhesive layer should be always formed on the part where the photoelectric conversion layer is not formed between the first and second electrode layers, in order to prevent a short circuit between the first and second electrode layers.

In particular, the adhesive layer is preferably formed so as to surround the outer periphery of the photoelectric conversion layer. This can increase the adhesion between the first and second electrode layers and prevent water and oxygen from entering the photoelectric conversion layer.

The adhesive layer may be formed using any adhesive as long as the adhesive has insulating properties and is capable of bonding the first and second electrode layers together. For example, a photo-curable resin, a thermosetting resin, or a thermoplastic resin may be used as an adhesive. Among them, a thermosetting resin is preferred, and thermosetting epoxy resin is particularly preferred.

The method of forming the adhesive layer may be any method by which the adhesive layer can be placed at the desired position. In general, a method of applying an adhesive is used. Examples of the method of applying an adhesive include an inkjet method, a dispenser method, a micro gravure coating method, a gravure coating method, a bar coating method, a roll coating method, a wire bar coating method, a dip coating method, a die coating method, a flexo printing method, an offset printing method, and a screen printing method. In particular, an inkjet method, a disperser method, and a screen printing method are preferably used.

While the adhesive may be applied onto the first or second electrode layer, it is generally applied onto the first electrode layer.

When the adhesive is a thermosetting resin, the adhesive layer can be formed, for example, by a process of applying the adhesive, then thermocompression-bonding the metal base material (second electrode layer) onto the photoelectric conversion layer, and thermally curing the adhesive. When the adhesive is a thermoplastic resin, the adhesive layer can be formed, for example, by a process of applying the adhesive, then thermocompression-bonding the metal base material (second electrode layer) onto the photoelectric conversion layer, and heating and cooling the adhesive. When the adhesive is a photo-curable resin, the adhesive layer can be formed, for example, by a process of applying the adhesive, then thermocompression-bonding the metal base material (second electrode layer) onto the photoelectric conversion layer, and photo-curing the adhesive. When the adhesive is a photo-curable resin, the adhesive may be further thermally cured after it is photo-cured.

3. Photoelectric Conversion Layer

The photoelectric conversion layer used in the invention is formed between the first and second electrode layers. The term “photoelectric conversion layer” refers to a member having a function of contributing to the charge separation in the organic thin film solar cell and transporting the generated electrons and holes to the opposite electrodes, respectively.

The photoelectric conversion layer may be a single layer having both an electron accepting function and an electron donating function (a first mode) or a laminate of an electron accepting layer having an electron accepting function and an electron donating layer having an electron donating function (a second mode). Hereinafter, each mode is described.

(1) First Mode

In the invention, a first mode of the photoelectric conversion layer is a single layer having both an electron accepting function and an electron donating function, which contains an electron donating material and an electron accepting material. In this photoelectric conversion layer, charge separation is generated based on the p-n junction formed therein, so that it functions by itself.

While such an electron donating material may be any material having an electron donating function, it is preferably capable of being formed into a film by a wet coating method, and in particular, it is preferably an electron-donating, conductive, polymer material.

The conductive polymer is a so-called π-conjugated polymer, which includes a π-conjugated system, in which a carbon-carbon or heteroatom-containing double or triple bond and a single bond are linked alternately, and exhibits semiconducting properties. The conductive polymer material has developed π-conjugation in the main polymer chain and therefore is basically advantageous in transporting charges in the main chain direction. In addition, the electron transfer mechanism of the conductive polymer is mainly hopping conduction between π-laminated molecules, and therefore, the conductive polymer material is advantageous in transporting charges not only in the main polymer chain direction but also in the thickness direction of the photoelectric conversion layer. When a coating liquid including a solution or dispersion of the conductive polymer material in a solvent is used, a film of the conductive polymer material can be easily formed by a wet coating method. Therefore, the conductive polymer material is advantageous in that a large-area organic thin film solar cell can be produced with it at low cost without the need for expensive equipment.

Examples of the electron-donating, conductive, polymer material include polyphenylene, polyphenylene vinylene, polysilane, polythiophene, polycarbazole, polyvinylcarbazole, porphyrin, polyacetylene, polypyrrole, polyaniline, polyfluorene, polyvinylpyrene, polyvinylanthracene, derivatives thereof, and copolymers thereof, or phthalocyanine-containing polymers, carbazole-containing polymers, and organometallic polymers.

Among the above, preferably used are thiophene-fluorene copolymers, polyalkylthiophene, phenylene ethynylene-phenylene vinylene copolymers, phenylene ethynylene-thiophene copolymers, phenylene ethynylene-fluorene copolymers, fluorene-phenylene vinylene copolymers, and thiophene-phenylene vinylene copolymers. These are appropriately different in energy level from many electron accepting materials.

For example, a detailed method for synthesis of a phenylene ethynylene-phenylene vinylene copolymer (poly[1,4-phenyleneethynylene-1,4-(2,5-dioctadodecyloxyphen ylene)-1,4-phenyleneethene-1,2-diyl-1,4-(2,5-dioctadodecylo xyphenylene)ethene-1,2-diyl]) is described in Macromolecules, 35, 3825 (2002) or Mcromol. Chem. Phys., 202, 2712 (2001).

While the electron accepting material may be any materials having an electron accepting function, it is preferably capable of being formed into a film by a wet coating method, and in particular, it is preferably an electron-accepting, conductive, polymer material. This is because the conductive polymer material has advantages as described above.

Examples of the electron-accepting, conductive, polymer material include polyphenylene vinylene, polyfluorene, derivatives thereof, and copolymers thereof, or carbon nanotubes, fullerene derivatives, CN or CF₃ group-containing polymers, and —CF₃-substituted polymers thereof. Specific examples of polyphenylene vinylene derivatives include CN-PPV (poly[2-methoxy-5-(2′-ethylhexyloxy)-1,4-(1-cyanovinylene)p henylene]) and MEH-CN-PPV (poly[2-methoxy-5-(2′-ethylhexyloxy)-1,4-(1-cyanovinylene)p henylene]).

An electron accepting material doped with an electron donating compound, an electron donating material doped with an electron accepting compound or the like may also be used. In particular, a conductive polymer material doped with such an electron donating or accepting compound is preferably used. This is because the conductive polymer material has developed π-conjugation in the main polymer chain and therefore is basically advantageous in transporting charges in the main chain direction and because charges are produced in the π-conjugated main chain by the doping with an electron donating compound or an electron accepting compound so that the electric conductivity can be significantly increased.

The above electron-accepting, conductive, polymer material may be used and doped with an electron donating compound. Examples of the electron donating compound that may be used as a dopant include Lewis bases such as alkali metals and alkaline earth metals, such as Li, K, Ca, and Cs. Lewis bases act as electron donors.

The above electron-donating, conductive, polymer material may be used and doped with an electron accepting compound. Examples of the electron accepting compound that may be used as a dopant include Lewis acids such as FeCl₃ (III) , AlCl₃, AlBr₃, AsF₆, and halogen compounds. Lewis acids act as electron acceptors.

The thickness of the photoelectric conversion layer used may be that used in a common bulk hetero-junction organic thin film solar cell. Specifically, the thickness may be set in the range of 0.2 nm to 3,000 nm, and preferably in the range of 1 nm to 600 nm. If the thickness is more than the above range, the volume resistance of the photoelectric conversion layer may increase. If the thickness is less than the above range, the layer may fail to sufficiently absorb light.

The mixing ratio between the electron donating material and the electron accepting material is appropriately controlled to be optimal depending on the type of the materials used.

While the photoelectric conversion layer may be formed by any method capable of uniformly forming a film with a predetermined thickness, it is preferably formed using a wet coating method. When a wet coating method is used, the photoelectric conversion layer can be formed in the air, so that the cost can be reduced and that a large-area product can be easily formed.

A coating liquid for forming the photoelectric conversion layer may be applied by any method capable of uniformly applying the coating liquid, such as die coating, spin coating, dip coating, roll coating, bead coating, spray coating, bar coating, gravure coating, inkjet process, screen printing, or offset printing.

In particular, the photoelectric conversion layer coating liquid is preferably applied by a method capable of controlling the thickness mainly based on the amount of coating. Examples of such a method capable of controlling the thickness mainly based on the amount of coating include die coating, bead coating, bar coating, gravure coating, inkjet process, and printing methods such as screen printing and offset printing. Printing methods are suitable in forming a large-area organic thin film solar cell.

After the photoelectric conversion layer coating liquid is applied, the coating film formed may be subjected to a drying process. In this case, the solvent and so on can be quickly removed from the photoelectric conversion layer coating liquid so that productivity can be increased.

The drying process may be performed using a common method such as drying by heating, drying by blowing, vacuum drying, or drying by infrared heating.

(2) Second Mode

In the invention, a second mode of the photoelectric conversion layer is a laminate of an electron accepting layer having an electron accepting function and an electron donating layer having an electron donating function. Hereinafter, the electron accepting layer and the electron donating layer are described.

(Electron Accepting Layer)

The electron accepting layer used in this mode has an electron accepting function and contains an electron accepting material.

While such an electron accepting material may be of any type capable of functioning as an electron acceptor, it is preferably capable of being formed into a film by a wet coating method, and in particular, it is preferably an electron-accepting, conductive, polymer material. Such a conductive polymer material has the advantages described above. Specifically, the conductive polymer material may be the same as the electron-accepting, conductive, polymer material used in the first mode of the photoelectric conversion layer.

The thickness of the electron accepting layer used may be that used in a common bilayer organic thin film solar cell. Specifically, the thickness may be set in the range of 0.1 nm to 1,500 nm, and preferably in the range of 1 nm to 300 nm. If the thickness is more than the above range, the volume resistance of the electron accepting layer may increase. If the thickness is less than the above range, the layer may fail to sufficiently absorb light.

The electron accepting layer may be formed by the same method as the method of forming the first mode of the photoelectric conversion layer.

(Electron Donating Layer)

The electron donating layer used in this mode has an electron donating function and contains an electron donating material.

While such an electron donating material may be of any type capable of functioning as an electron donator, it is preferably capable of being formed into a film by a wet coating method, and in particular, it is preferably an electron-donating, conductive, polymer material. Such a conductive polymer material has the advantages described above. Specifically, the conductive polymer material may be the same as the electron-donating, conductive, polymer material used in the first mode of the photoelectric conversion layer.

The thickness of the electron donating layer used may be that used in a common bilayer organic thin film solar cell. Specifically, the thickness may be set in the range of 0.1 nm to 1,500 nm, and preferably in the range of 1 nm to 300 nm. If the thickness is more than the above range, the volume resistance of the electron donating layer may increase. If the thickness is less than the above range, the layer may fail to sufficiently absorb light.

The electron donating layer may be formed by the same method as the method of forming the first mode of the photoelectric conversion layer.

4. First Electrode Layer

In the invention, the first electrode layer is an electrode formed on the transparent substrate and opposed to the second electrode layer. The first electrode layer is generally used as an electrode (hole extraction electrode) to extract holes generated in the photoelectric conversion layer. In the invention, the first electrode layer side forms a light receiving surface.

The first electrode layer may be of any type capable of serving as a light receiving side electrode, which may be a transparent electrode or a laminate of a transparent electrode and a patterned auxiliary electrode.

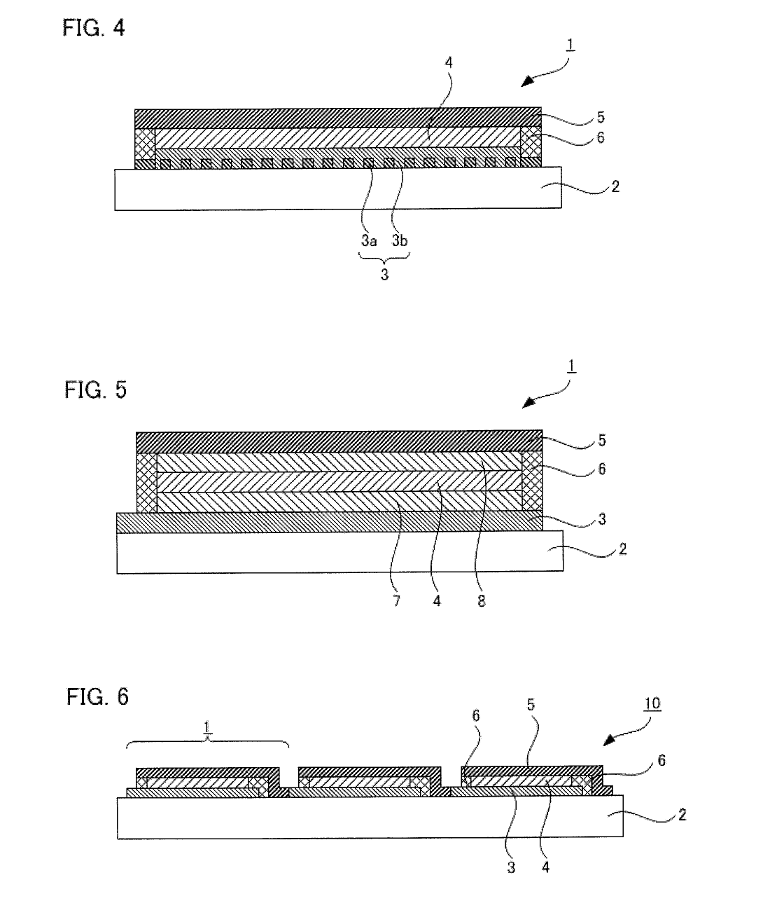

As illustrated in FIG. 4, when the first electrode layer 3 is a laminate of a patterned auxiliary electrode 3a and a transparent electrode 3b, the sheet resistance of the auxiliary electrode can be sufficiently reduced so that the total resistance of the first electrode layer can be reduced, even though the transparent electrode has a relatively high sheet resistance. Therefore, the generated power can be efficiently collected.

Hereinafter, the transparent electrode and the auxiliary electrode are described.

(1) Transparent Electrode

The transparent electrode that may be used in the invention is formed on the transparent substrate.

Such a transparent electrode may be made of any material having conductivity and transparency, such as In—Zn—O (IZO), In—Sn—O (ITO), ZnO—Al, or Zn—Sn—O. In particular, it is preferred that such a material should be appropriately selected taking into account the work function and other characteristics of the material used to form the second electrode layer. For example, when the second electrode layer is made of a material with a low work function, the transparent electrode is preferably made of a material with a high work function. ITO is preferably used as a material having conductivity, transparency, and a high work function.

The transparent electrode preferably has a total light transmittance of 85% or more, more preferably 90% or more, in particular, and preferably 92% or more. When the total light transmittance of the transparent electrode is in the above range, light can sufficiently pass through the transparent electrode, so that the photoelectric conversion layer can efficiently absorb light.

The total light transmittance is the value measured in the visible light region using SM Color Computer (model: SM-C) manufactured by Suga Test Instruments Co., Ltd.

The transparent electrode preferably has a sheet resistance of 20 Ω/□ or less, more preferably 10 Ω/□ or less, in particular, and preferably 5 Ω/□ or less. If the sheet resistance is more than the above range, the generated charges may fail to be sufficiently transferred to the external circuit.

The sheet resistance is the value measured according to JIS R1637 (Test Method for Resistivity of Fine Ceramic Thin Films with a Four-Point Probe Array) using a surface resistance meter manufactured by Mitsubishi Chemical Corporation (Loresta MCP™: four point probe).

The transparent electrode may be a single layer or a laminate of materials with different work functions.

The thickness of the transparent electrode, which corresponds to the thickness of a single layer or the total thickness of two or more layers, is preferably in the range of 0.1 nm to 500 nm, and in particular, preferably in the range of 1 nm to 300 nm. If the thickness is less than the above range, the transparent electrode may have too high sheet resistance, so that the generated charges may fail to be sufficiently transferred to the external circuit. If the thickness is more than the above range, the total light transmittance may be reduced, so that the photoelectric conversion efficiency may be reduced.

The transparent electrode may be formed using a general electrode-forming method.

(2) Auxiliary Electrode

The auxiliary electrode that may be used in the invention is formed in a certain pattern on the transparent substrate. The auxiliary electrode generally has a resistance value lower than that of the transparent electrode.

The material used to form the auxiliary electrode is generally metal. Examples of the metal used to form the auxiliary electrode include electrically-conductive metals such as aluminum (Al), gold (Au), silver (Ag), cobalt (Co), nickel (Ni), platinum (Pt), copper (Cu), titanium (Ti), iron (Fe), stainless steel metals, aluminum alloys, copper alloys, titanium alloys, iron-nickel alloys, and nickel-chromium (Ni—Cr) alloys. Among these electrically-conductive metals, metals with relatively low electrical resistance are preferred. Such electrically-conductive metals include Al, Au, Ag, and Cu.

The auxiliary electrode may be a single layer made of an electrically-conductive metal as described above or a laminate of an electrically-conductive metal layer and a contact layer, which are appropriately laminated to improve adhesion to the substrate or the transparent electrode. Examples of the material used to form the contact layer include nickel (Ni), chromium (Cr), nickel-chromium (Ni—Cr), titanium (Ti), and tantalum (Ta). The contact layer is placed on the electrically-conductive metal layer so that the desired adhesion between the auxiliary electrode and the substrate or the transparent electrode can be obtained, and the contact layer or layers may be laminated on only one or both sides of the electrically-conductive metal layer.

A preferred metal may be selected depending on factors such as the work function of the second electrode layer-forming material. For example, when the work function and the like of the second electrode layer-forming material is taken into account, it is preferred that the metal used to form the auxiliary electrode should have a high work function, because the first electrode layer serves as a hole extraction electrode. Specifically, Al is preferably used.

The auxiliary electrode may be of any shape as long as it has a certain pattern, and the shape of the auxiliary electrode is appropriately selected depending on factors such as the desired conductivity, transparency, or strength. For example, the auxiliary electrode may have a mesh part, which is in the form of a mesh, and a frame part placed around the mesh part, or may consist of a mesh part, which is in the form of a mesh.

When the auxiliary electrode has a mesh part and a frame part, the mesh and frame parts may be arranged in such a manner that, for example, when the auxiliary electrode is rectangular, the frame part surrounds the four sides of the mesh part, three sides of the mesh part, or two sides of the mesh part, or placed along one side of the mesh part. In particular, the frame part is preferably placed to surround four or three sides of the mesh part, so that electric power can be efficiently collected.

The mesh part may have any shape as long as it is in the form of a mesh, and the shape may be appropriately selected depending on factors such as the desired conductivity, transparency, or strength. For example, it may be a polygonal lattice structure such as a triangular, quadrangular, or hexagonal lattice structure, a circular lattice structure, or any other lattice structure. The polygonal or circular “lattice structure” means a structure in which polygons or circles are periodically arranged. In the polygonal or circular lattice structure, for example, polygonal openings may be straightly arranged or zigzag arranged.

In particular, the mesh part preferably has a hexagonal lattice structure or a parallelogram lattice structure. This is because the current flowing through the mesh part can be prevented from being localized. Particularly in the case of a hexagonal lattice structure, hexagonal openings are preferably zigzag arranged (in a so-called honeycomb pattern). In the case of a parallelogram lattice structure, the parallelogram preferably has an acute angle in the range of 40° to 80°, more preferably in the range of 50° to 70°, and even more preferably in the range of 55° to 65°.

Since the auxiliary electrode itself basically does not transmit light, the light enters the photoelectric conversion layer from the openings of the mesh part of the auxiliary electrode. Therefore, the mesh part of the auxiliary electrode preferably has relatively large openings. Specifically, the mesh part of the auxiliary electrode preferably has an opening ratio in the range of about 50% to about 98%, more preferably in the range of 70% to 98%, and even more preferably in the range of 80% to 98%.

In the auxiliary electrode, the pitch of the openings of the mesh part and the line width of the mesh part may be appropriately selected depending on the area of the whole of the auxiliary electrode or other features.

The line width of the frame part may also be appropriately selected depending on the area of the whole of the auxiliary electrode or other features.

The thickness of the auxiliary electrode is not restricted, as long as it is such that no short circuit occurs between the first and second electrode layers, and it may be appropriately selected depending on factors such as the thickness of the photoelectric conversion layer, the hole extraction layer, or the electron extraction layer. Specifically, when the total thickness of the layers formed between the first and second electrode layers (such as the photoelectric conversion layer, the hole extraction layer, and the electron extraction layer) is normalized as 1, the thickness of the auxiliary electrode is preferably 5 or less, more preferably 3 or less, even more preferably 2 or less, in particular, preferably 1.5 or less, and most preferably 1 or less. If the thickness of the auxiliary electrode exceeds the above range, a short circuit may occur between the electrodes. More specifically, the thickness of the auxiliary electrode is preferably in the range of 100 nm to 1,000 nm, more preferably in the range of 200 nm to 800 nm, even more preferably in the range of 200 nm to 500 nm, and in particular, preferably in the range of 200 nm to 400 nm. If the thickness of the auxiliary electrode is less than the above range, the sheet resistance of the auxiliary electrode may be too high. If the thickness of the auxiliary electrode is more than the above range, a short circuit may occur between the electrodes.

Particularly when the photoelectric conversion layer is formed on the first electrode layer by a method capable of controlling the thickness mainly based on the amount of coating, the thickness of the auxiliary electrode is preferably in the range of 200 nm to 300 nm. When the photoelectric conversion layer is formed on the first electrode layer by the method capable of controlling the thickness mainly based on the amount of coating, setting the thickness of the auxiliary electrode at more than the above range can make it difficult to cover the edge of the mesh or frame part of the auxiliary electrode, so that a short circuit may be more likely to occur between the electrodes. Also if the thickness of the auxiliary electrode is more than the above range, the photoelectric conversion layer may be formed with a thickness greater than the desired thickness due to the surface tension. If the photoelectric conversion layer is too thick, it may exceed the electron diffusion length and the hole diffusion length, so that the conversion efficiency may be reduced. The thickness of the auxiliary electrode is preferably controlled so that the photoelectric conversion layer is prevented from being formed with a thickness greater than the desired thickness due to the surface tension. Particularly, the distance which holes and electrons can travel in a photoelectric conversion layer is known to be about 100 nm, and also from this point, the thickness of the auxiliary electrode is preferably controlled so that the photoelectric conversion layer is prevented from being formed with a thickness greater than the desired thickness due to the surface tension.

On the other hand, for example, when the photoelectric conversion layer is formed by spin coating, the centrifugal force can make the film uniform, so that the edge of the auxiliary electrode can be covered even when the auxiliary electrode is relatively thick. In the case of spin coating, the thickness can also be controlled by the number of revolutions, which makes it possible to obtain a uniform film even when the auxiliary electrode is relatively thick.

Thus, when the photoelectric conversion layer is formed by the method capable of controlling the thickness mainly based on the amount of coating, the above range is particularly preferred.

The auxiliary electrode may have any sheet resistance lower than the sheet resistance of the transparent electrode. Specifically, the auxiliary electrode preferably has a sheet resistance of 5 Ω/□ or less, more preferably 3 Ω/□ or less, even more preferably 1 Ω/□ or less, in particular, preferably 0.5 Ω/□ or less, and most preferably 0.1 Ω/□ or less. If the sheet resistance of the auxiliary electrode is more than the above range, the desired power generation efficiency cannot be obtained in some cases.

The sheet resistance is the value measured according to JIS R1637 (Test Method for Resistivity of Fine Ceramic Thin Films with a Four-Point Probe Array) using a surface resistance meter manufactured by Mitsubishi Chemical Corporation (Loresta MCP™: four point probe).

Concerning the order of laminating the transparent electrode and the auxiliary electrode, the auxiliary electrode and the transparent electrode may be laminated in this order on the transparent substrate, or the transparent electrode and the auxiliary electrode may be laminated in this order on the transparent substrate. In particular, the auxiliary electrode and the transparent electrode are preferably laminated in this order on the transparent substrate. This is because a larger contact area between the transparent electrode and the photoelectric conversion layer or the hole extraction layer or the like can provide better adhesion at the interface and achieve higher hole transfer efficiency.

Concerning where the auxiliary electrode is formed, when the adhesive layer is formed, the auxiliary electrode is preferably placed in contact with the adhesive layer. When the adhesive layer is formed in contact with the auxiliary electrode made of metal and with the second electrode layer made of a metal base material, the adhesive strength can be increased.

When the transparent electrode and the auxiliary electrode are laminated in this order on the transparent substrate, the auxiliary electrode can be placed in contact with the adhesive layer. For example, as shown in FIG. 4, when the auxiliary electrode 3a and the transparent electrode 3b are laminated in this order on the transparent substrate, a region where the transparent electrode 3b is not laminated may be formed on the auxiliary electrode 3a so that the auxiliary electrode 3a can be placed in contact with the adhesive layer 6.

Examples of the method of forming the auxiliary electrode include, but not limited to, a method that includes forming a metal thin film on the entire surface and then patterning the metal thin film into a mesh structure, or a method of directly forming a mesh conductor. These methods are appropriately selected depending on factors such as the auxiliary electrode-forming material or structure.

The metal thin film is preferably formed by a vacuum film forming method such as vacuum deposition, sputtering, or ion plating. Therefore, the auxiliary electrode is preferably a metal thin film formed by a vacuum film forming method. Metal species produced by a vacuum film forming method can have a lower inclusion content and a lower specific resistance than plating films. Metal thin films formed by a vacuum film forming method can also have a lower specific resistance than films produced with a Ag paste or the like. The vacuum film forming method is also suitable in forming a metal thin film with a uniform thickness of 1 μm or less, preferably 500 nm or less, under precise control of the thickness.

The metal thin film may be patterned by any method capable of forming the desired pattern with high precision, an example of which is photo-etching.

5. Transparent Substrate

The transparent substrate used in the invention may be of any type, such as a non-flexible transparent rigid member such as a quartz glass, PYREX (registered trademark), or a synthetic quartz plate; or a flexible transparent member such as a transparent resin film or an optical resin plate.

In particular, the transparent substrate is preferably a flexible material such as a transparent resin film. The transparent resin film has good workability, is useful for reducing the manufacturing cost or the weight and for forming a crack-resistant organic thin film solar cell, and therefore can be used in a wide variety of applications including curved surface applications.

6. Hole Extraction Layer

In the invention, as illustrated in FIG. 5, a hole extraction layer 7 may be formed between the photoelectric conversion layer 4 and the first electrode layer 3. The hole extraction layer is provided to facilitate the extraction of holes from the photoelectric conversion layer to the hole extraction electrode. This increases the efficiency of the extraction of holes from the photoelectric conversion layer to the hole extraction electrode, so that the photoelectric conversion efficiency can be increased.

The material used to form the hole extraction layer may be any material capable of stabilizing the extraction of holes from the photoelectric conversion layer to the hole extraction electrode. Examples thereof include electrically-conductive organic compounds such as doped polyaniline, polyphenylene vinylene, polythiophene, polypyrrole, polyparaphenylene, polyacetylene, and triphenyldiamine (TPD); and organic materials that form a charge transfer complex composed of an electron donating compound such as tetrathiofulvalene or tetramethylphenylenediamine and an electron accepting compound such as tetracyanoquinodimethane or tetracyanoethylene. A thin film of a metal or the like such as Au, In, Ag, or Pd may also be used. The thin film of a metal or the like may be used alone or in combination with the above-mentioned organic material.

In particular, polyethylenedioxythiophene (PEDOT) and triphenyldiamine (TPD) are preferably used.

The thickness of the hole extraction layer is preferably in the range of 10 nm to 200 nm when produced using the organic material or preferably in the range of 0.1 nm to 5 nm when it is the metal thin film.

7. Hole Extraction Layer

In the invention, as illustrated in FIG. 5, an electron extraction layer 8 may be formed between the photoelectric conversion layer 4 and the second electrode layer 5. The electron extraction layer is provided to facilitate the extraction of electrons from the photoelectric conversion layer to the electron extraction electrode. This increases the efficiency of the extraction of electrons from the photoelectric conversion layer to the electron extraction electrode, so that the photoelectric conversion efficiency can be increased.

The material used to form the electron extraction layer may be any material capable of stabilizing the extraction of electrons from the photoelectric conversion layer to the electron extraction electrode. Examples thereof include electrically-conductive organic compounds such as doped polyaniline, polyphenylene vinylene, polythiophene, polypyrrole, polyparaphenylene, polyacetylene, and triphenyldiamine (TPD); and organic materials that form a charge transfer complex composed of an electron donating compound such as tetrathiofulvalene or tetramethylphenylenediamine and an electron accepting compound such as tetracyanoquinodimethane or tetracyanoethylene. A metal-doped layer with an alkali or alkaline earth metal may also be used. Preferred materials include metal-doped layers comprising bathocuproin (BCP) or bathophenanthron (Bphen) and Li, Cs, Ba, Sr, or the like.

8. Other Features

In addition to the components described above, if necessary, the organic thin film solar cell of the invention may have any of the components mentioned below. For example, the organic thin film solar cell of the invention may have a protective sheet or a functional layer such as a filler layer, a barrier layer, a protective hard-coat layer, a strength supporting layer, an anti-fouling layer, a high light-refection layer, a light confining layer, or a sealer layer. A bonding layer may also be formed between the respective functional layers depending on the layered structure.

These functional layers may be those disclosed in publications such as JP-A No. 2007-73717.

In the invention, power can be easily drawn from the first and second electrode layers to the external circuit as described above. For example, power can be drawn to the external circuit through positive and negative metal electrode terminals in contact with the surfaces of the first and second electrode layers, respectively.

B. Organic Thin Film Solar Cell Module

The organic thin film solar cell module of the invention comprises a plurality of the above-mentioned organic thin film solar cells connected in series or parallel.

FIG. 6 is a schematic cross-sectional view showing an example of the organic thin film solar cell module of the invention. FIG. 6 shows that an organic thin film solar cell module 10 comprises three cells (organic thin film solar cells 1) connected in series. Each cell (organic thin film solar cell 1) comprises a transparent substrate 2, a first electrode layer 3 formed on the transparent substrate 2, a photoelectric conversion layer 4 formed on the first electrode layer 3, a second electrode layer 5 that is formed on the photoelectric conversion layer 4 and made of a metal base material, and an adhesive layer 6 that has insulating properties and is formed between the first and second electrode layers 3 and 5 so as to surround the periphery of the photoelectric conversion layer 4.

In the organic thin film solar cell module, the adhesive layer having insulating properties is formed, so that no short circuit occurs between the first and second electrode layers in each cell. In addition, the formation of the adhesive layer having insulating properties prevents a shirt circuit between the first electrode layers of the adjacent cells and between the second electrode layers of the adjacent cells.

According to the invention, since the module has the organic thin film solar cells described above, the second electrode layers do not need to be sealed from above using a sealing substrate, and not only the power can be easily drawn from the first and second electrode layers to the external circuit, but also the plurality of the organic thin film solar cells can be easily connected using the first and second electrode layers.

The plurality of the organic thin film solar cells may be connected in series or parallel only or in a combination of series and parallel, as long as the desired electromotive force can be obtained. In addition, a plurality of the organic thin film solar cells may be formed and connected on the same transparent substrate, or a plurality of the organic thin film solar cells may be each independently formed and connected through wiring or the like.

The organic thin film solar cell has been described in detail in the section “A. organic thin film solar cell,” and therefore, a repeated description thereof is omitted here.

The above embodiments are not intended to limit the scope of the invention. The above embodiments are described by way of example only, and it will be understood that many variations are possible with substantially the same feature as the technical idea recited in the scope of claims to produce the same effect, and all of such variations are within the scope of the invention.

### EXAMPLES

Hereinafter, the invention is more specifically described with reference to examples.

### Example 1

A SiO₂ thin film was formed on a 125 μm thick PET film substrate by PVD method, and an ITO film (thickness: 150 nm, sheet resistance: 20 Ω/□) as a transparent electrode was formed on the upper surface of the SiO₂ thin film by reactive ion plating (power: 3.7 kW, oxygen partial pressure: 73%, deposition pressure: 0.3 Pa, deposition rate: 150 nm/minute, substrate temperature: 20° C.) using a pressure gradient plasma gun.

The ITO film-carrying substrate was then washed with acetone, a substrate cleaning solution, and IPA. Subsequently, a film of a conductive polymer paste (a dispersion of poly-(3,4-ethylenedioxythiophene)) was formed on the ITO film so that it would have an area larger than that of the ITO film and that the ITO film would be partially exposed, and then dried at 100° C. for 10 minutes to form a buffer layer.

Subsequently, a polythiophene (P3HT: poly(3-hexylthiophene-2,5-diyl)) and C60PCBM ([6,6]-phenyl-C61-butyric acid mettric ester, manufactured by Nano-C, Inc.) were dissolved in bromobenzene to form a photoelectric conversion layer coating liquid with a solids content of 1.4 wt %. Subsequently, the coating liquid was applied onto the buffer layer by bar coating method so that the coating would have the same area as the buffer layer, and then dried at 100° C. for 10 minutes to form a photoelectric conversion layer.

Subsequently, an insulating adhesive containing a thermosetting epoxy resin was applied to part of the ITO film, on which neither the buffer layer nor the photoelectric conversion layer was formed.

Subsequently, a 10 μm thick aluminum sheet was laminated onto the photoelectric conversion layer by thermal lamination method to form a metal electrode. The insulating adhesive was then thermally cured. As a result, the ITO film and the aluminum sheet were bonded together with the insulating adhesive at the region where they overlapped.

In the resulting organic thin film solar cell, a positive electrode metal clip and a negative electrode metal clip were brought into contact with the ITO film and the aluminum sheet, respectively, and the power was drawn to the external circuit through them.

### REFERENCE SIGNS LIST

1 organic thin film solar cell
2 Transparent substrate
3 First electrode layer
3a Auxiliary electrode
3b Transparent electrode
4 Photoelectric conversion layer
5 Second electrode layer
6 Adhesive layer
7 Hole extraction layer
8 Electron extraction layer
10 organic thin film solar cell module

1. An organic thin film solar cell, comprising:
a transparent substrate;
a first electrode layer formed on the transparent substrate;
a photoelectric conversion layer formed on the first electrode layer; and
a second electrode layer that is formed on the photoelectric conversion layer and made of a metal base material.

2. The organic thin film solar cell according to claim 1, further comprising an adhesive layer that has insulating properties, and is formed along an outer periphery of the photoelectric conversion layer and between the first electrode layer. and the second electrode layer.

3. The organic thin film solar cell according to claim 1, wherein the metal base material is a metal foil.

4. An organic thin film solar cell module, comprising a plurality of the organic thin film solar cells according to claim 1 connected in series or parallel.
